(19) United States
(12) Patent Application Publication
(10) Pub. No.: US 2009/0023235 A1
(43) Pub. Date: Jan. 22, 2009

(54) Method and Apparatus for Improved Printed Cathodes for Light-Emitting Devices

(76) Inventors: John D. MacKenzie, San Carlos, CA (US); Melissa Kreger, Santa Cruz, CA (US)

Correspondence Address: PILLSBURY WINTHROP SHAW PITTMAN LLP, P.O. BOX 10500, MCLEAN, VA, 22102, US

(21) Appl. No.: 11/780,452

(22) Filed: Jul. 19, 2007

(51) Int. Cl. H01L 51/56

(52) U.S. Cl. 438/29; 257/E51.018

(57) ABSTRACT

Rapid thermal processing of printed cathodes for light-emitting polymer devices (LEPDs) to prevent detrimental cathode ink/LEP layer interactions is described herein. The ink layer printed cathode can be thinned curing fabrication using high mesh count screens, calendered mesh screens, high squeegee pressures, high hardness squeegees, high squeegee angles and combinations thereof. Alone, or in combination with, a thinned ink layer, the printed cathode can be cured using reduced time hot plate processing, infrared processing, heated gas flow processing, or combinations thereof.

### BACKGROUND OF THE INVENTION

1. Field of the Invention

Generally, this disclosure relates to light-emitting devices (LEDs). More specifically, it relates to a method and apparatus for improved printed cathodes for LEDs.

2. Description of the Related Art

In recent years, light-emitting polymer devices (LEPDs) have been developed for use as indicators, back-lighting in liquid crystal displays and instrument panels, and to replace vacuum fluorescent and liquid crystal displays. There are several patents that teach how different LEPD layers enable the efficient production of electrically stimulated light emission. For instance, U.S. Pat. No. 6,284,435 to Cao discloses electrically active polymer compositions and their use in efficient, low operating voltage, polymer light-emitting diodes with air-stable cathodes. Additionally, U.S. Pat. No. 5,399,502 to Friend et al. shows a method of manufacturing electroluminescent devices. Finally, U.S. Pat. No. 5,869,350 to Heeger et al. demonstrates the fabrication of visible light emitting diodes from soluble semiconducting polymers.

Screen printing, gravure printing, flexographic printing and ink-jet printing can be cost-effective fabrication techniques that can be used to deposit some or all of the layers of LEPDs. As an example, U.S. Patent Application Publication No. 2002/0013013 to Victor et al., which is fully incorporated herein by reference for all purposes, describes a novel screen printing technique for LEPDs. Printing techniques, as opposed to conventional vacuum deposition, photolithography and subtractive patterning, are particularly attractive for LEPD fabrication because they can have high throughput, patterning can be easily customized and they are capable of processing flexible substrates. Furthermore, printing operations that can be carried out in ambient conditions, or printed layers that are stable in ambient conditions at all or some intermediate stages of the fabrication and encapsulation process, can make processing considerably less expensive and complex.

In conventional organic and polymer light emitting device processing, even those typical approaches that utilize printing to deposit the emitting and transport layers, the top electrode, i.e., the cathode, is not directly printed (i.e. via liquid processes under atmospheric conditions). Instead, techniques such as vacuum evaporation of low work function metals have been used for this top electrode, which can greatly increase the complexity and cost of fabricating the LEPDs. In addition to the costs of the deposition process itself, the low work function and/or reactive electrode or electrode interlayers (e.g., such as Calcium (Ca), Barium (Ba), Lithium Fluoride (LiF) or others) usually dictate that all subsequent processing be performed in oxygen and/or water free environments to prevent degradation.

In U.S. Patent Application Publication Nos. 2003/0151700 and 2003/0153141, both to Carter et al., which are fully incorporated by reference for all purposes, ink formulations, compositions, and structures for printed LEPD and printed cathode layers which can be stable in air are described. These approaches outline a path toward low cost, high-volume, web-printable LEPDs on flexible and rigid substrates through the high throughput, reduced cost and reduced complexity inherent to printing. However, printed LEP and/or printed electrode devices can require higher voltages and/or have lower efficiencies than their vacuum or area-coated counterparts (such as spin-coated). It would therefore be helpful to reduce this voltage and improve the efficiency to allow for lower cost drivers, easier battery integration, lower power consumption, and so on. Furthermore, high voltages, low efficiencies and high current densities (either for the whole device or at localized areas) can lead to low operational-lifetimes and shelf-lifetimes which can be detrimental for many applications. Printed LEPD devices can have effective resistances ranging from 1.5 k ohms-cm² to 20 k ohms-cm² at bias voltages ranging from 3 volts to >30 volts for typical drive conditions in the range of 0.5 mA/cm² to 5 mA/cm² current density and luminances ranging from 30 Cd/m to 250 Cd/m². Efficiencies for ideal spin coated and evaporated LEPD devices can exceed 10 candelas per ampere (Cd/A). However, all-printed devices can range from 1-7 cd/A maximum efficiency.

FIG. 1 illustrates a simplified cross-sectional diagram of a printed LEPD on a flexible substrate as is know in the art today. Layer thicknesses are not to scale. As shown, a typical substrate 110 thickness may be between 100 and 200 microns and may be, for example, a plastic substrate composed of polyethylene teraphthalate (PET), poly ethylene napthalate (PEN), poly carbonate (PC) or similar. In some cases, to improve shelf life and product lifetime, the substrate includes a barrier film, composed of inorganic and/or organic materials, which restrict the ingress of water, oxygen and other species into the active areas of the device. Disposed on substrate 110 can be a transparent anode 120, such as indium-tin-oxide (ITO) layer, which can have a thickness between 50-300 nm. A light-emitting polymer 130, with a thickness between 200 nm and 1 micron can be disposed on transparent anode 120. Finally, a cathode 140 with a thickness of between 100 nm and 10 microns, depending on fabrication approach, can be disposed on light-emitting polymer 130.

One initial approach to printable cathode materials is to adapt conventional conducting inks, such as silver-flake (Ag-flake) ink, used for inorganic electroluminescent devices, flex circuit, membrane switch, and other applications. These inks are commercially available form a number of sources including Dupont, Acheson, Cookson, Conductive Compounds, Sumitomo MM, Englehard, Dow-Corning and others. These inks can be thermoplastic and thermoset inks, including binders and metallic particle and flake particles. Typically, thermal treatments are required to achieve mechanical properties, adhesion, high conductivities and efficient injection electrodes and interconnects for light-emitting devices. (See, “Understanding and measuring electrical resistivity in conductive inks and adhesives”, Banfield, D., SGIA Journal, June 2000.

This thermal treatment can perform several functions including: removal of solvents, removal or decomposition of additives or byproducts, melting of binders to allow particle settling, reaction of thermosetting binders, film shrinkage, better particle to particle contact, and nestling of particles for higher density and increased electrode-to-LEP contact area, particularly for flattened flakes or other non-spherical particles. For some lower temperature-curing inks suitable for use with flexible substrates, cure temperatures of 90° C. and above may be required for maximum cathode and interconnect performance. However, exposure to these temperatures for extended time periods can cause deterioration or variation of the properties of the underlying substrate, environmental barrier layers, anode materials, LEP materials or the interfaces of these materials, particularly if processing is carried out in air or relatively high oxygen and water containing atmosphere for the sake of process simplicity and minimized cost and time. Furthermore, exposure of the LEP-containing layer to liquid and/or solvent containing cathode ink can lead to degradation of the LEP layer and/or the LEP/cathode interface.

Therefore, what are needed are methods and systems concerning the printing and processing of inks to fabricate high performance, printed cathode LEPDs that produce low voltage, high brightness and/or high efficiency printed LEPDs by accelerating cathode curing and solvent removal while still achieving high conductivity and effective cathode to LEP-layer contact.

### SUMMARY OF THE DISCLOSURE

Rapid thermal processing of printed cathodes for light-emitting polymer devices (LEPDs) to prevent detrimental cathode ink/LEP layer interactions is described herein. The ink layer printed cathode can be thinned during fabrication using high mesh count screens, calendered mesh screens, high squeegee pressures, high hardness squeegees, high squeegee angles and combinations thereof. Alone, or in combination with a thinned ink layer, the printed cathode can be cured using reduced time hot plate processing, infrared processing, heated gas flow processing, or combinations thereof. Where it may be advantageous to have an overall thicker cathode layer for improved conductivity, particle-to-particle contact and/or nestling once the cathode has dried, the cathode layer can be advantageously deposited as a series of thinner wet layers as opposed to a single wet thicker layer.

### BRIEF DESCRIPTION OF THE DRAWINGS

Aspects and features of the present invention will become apparent to those ordinarily skilled in the art from the following detailed description of certain embodiments in conjunction with the accompanying drawings, wherein:

FIG. 1(a) illustrates a simplified cross-sectional diagram of a printed LEPD on flexible substrate as is known in the art today;

FIGS. 1(b)(1)-(3) illustrates a sequence of cross-sectional diagram of printing an LEPD on flexible substrate according to the present invention,

FIG. 2(a) illustrates an example of actual effects of using different cathode ink screen mesh configurations on printed cathode LEPD devices according to certain embodiments;

FIG. 2(b) shows the impact of different cathode mesh sizes on performance.

FIG. 3 illustrates an example of the effects of squeegee pressure on film thickness for two different squeegee hardnesses according to certain embodiments;

FIG. 4 illustrates resultant brightness comparisons for an LEPD given rapid hot plate cathode ink curing according to certain embodiments versus box oven annealing for an LEPD; and

FIG. 5 illustrates IR lamp versus box oven curing data from screen-printed LEPD devices based on Covion/Merck SY LEP emitters and a commercially-available silver screen paste ink cathode according to certain embodiments.

FIG. 6 illustrates a comparison of screen-printed LEPD device performance (luminance vs. time under constant current drive) for devices with a single cathode layer and devices with a multilayered printed cathode.

FIGS. 7(a)-(d) illustrate printing of a cathode using multiple thin cathode layers according to the present invention.

### DETAILED DESCRIPTION OF THE INVENTION

Embodiments will now be described in detail with reference to the drawings, which are provided as illustrative examples so as to enable those skilled in the art to practice the embodiments and are not meant to limit the scope of the disclosure. Where aspects of certain embodiments can be partially or fully implemented using known components or steps, only those portions of such known components or steps that are necessary for an understanding of the embodiments will be described, and detailed description of other portions of such known components or steps will be omitted so as not to make the disclosure overly lengthy or unclear. Further, certain embodiments are intended to encompass presently known and future equivalents to the components referred to herein by way of illustration.

Rapid thermal processing of printed cathodes for light-emitting polymer devices (LEPDs) to substantially prevent detrimental cathode ink/LEP layer interactions is described herein. Some novel innovations that can be included in certain embodiments include fast solvent removal, which can help prevent detrimental Ag ink solvent/LEP interface interactions and can also help prevent softening or flow of underlying LEP. Softening and flow of the underlying LEP can lead to Ag penetration into LEP layer and shorting. Preventing softening of the underlying LEP can also help prevent partial dissolution and/or redistribution of the LEP layer, which can lead to thickness and EL variation. Higher temperatures, provided in more detail hereinafter, can help enable good Ag ink particle settling/nestling for high lateral conductivity and Ag/LEP contact. Further, short heating times, also described further hereinafter, can help limit detrimental heating effects on LEP, LEP/cathode interface and low T substrate, and can help limit deformation, oxidation, and/or other reactions; and rapid transfer between the printing station and first stage drying operation.

Through techniques described herein, it is possible to minimize cathode solvent dissolution, LEP layer softening, or other effects that may lead to shorting or detrimental changes of underlying layer morphology, composition or chemistry can be minimized. Chemical or compositional changes can include leaching of components from LEP or transport layers, solvent degradation of materials, and the introduction of harmful solvent residues or other harmful surfactants, cosolvents, impurities or other species from the cathode ink in to the active layer of the device.

In a particular, embodiment, the rapid thermal processing includes disposing the conductive ink, and thereby the solvent, over the organic light emitting layer for a period of time that is less than about 1 minute before a majority of the solvent, and preferably more than 70% of the solvent, evaporates. Evaporation that occurs even more quickly is desirable.

In another embodiment, maximizing the volume percentage of solid, such that there is less than 40% solvent by volume and/or less than 25% solvent by weight, and thereby minimizing the amount of solvent, in the conductive ink also assists with the rapid thermal processing and a resulting device having better characteristics. Having even percentages where the amount of solvent is even less is further preferred, such as less than 20% solvent by weight.

In a particular embodiment, the solvent amount limit is in the lower parameter range for a typical printed Ag conductor in general applications. This is in order to minimize solvent deposited in the cathode ink layers. In such an embodiment the cathode ink layer deposit includes less than 10 g solvent/m2 of printed area, which is an estimate of the largest amount of solvent deposited in a cathode print pass based on the following Tables I and II that show a range of typical solvents, the range of ink deposits from the different screens described herein, and the upper range of solvent content/m2 of printed cathode ink area (40% solvent mass fraction).

TABLE 1

| | density [g/cc] |
|---|---|
| CB | 1.11 |
| Xylene | 0.87 |
| cyclohexanone | 0.95 |
| Anisole | 0.995 |
| carbitol acetate | 1.01 |
| Dbe | 1.09 |
| Gbl | 1.14 |
| Average | 1.02 |
| Hi | 1.14 |
| Lo | 0.87 |

TABLE II
Solvent content of printed cathode ink layer

| ink | solvent | solvent | solvent ave | solvent max |
|---|---|---|---|---|
| [cm3/m2] | fraction | [cm3/m2] | [g/m2] | [g/m2] |
| 22 | 0.4 | 8.8 | 9.0 | 10.0 |
| 12 | 0.4 | 4.8 | 4.9 | 5.5 |
| 8 | 0.4 | 3.2 | 3.3 | 3.6 |
| 4.2 | 0.4 | 1.68 | 1.7 | 1.9 |

In another embodiment, the solvent containing ink deposit is a solvent containing layer of less than 12 microns in thickness, which can be used in forming a cathode from multiple layers where each layer is less than 12 microns thick.

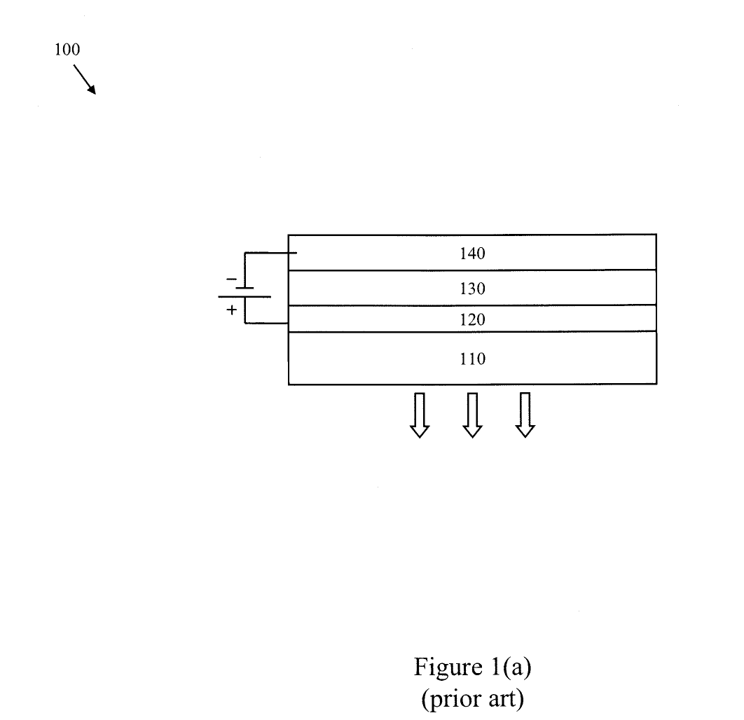

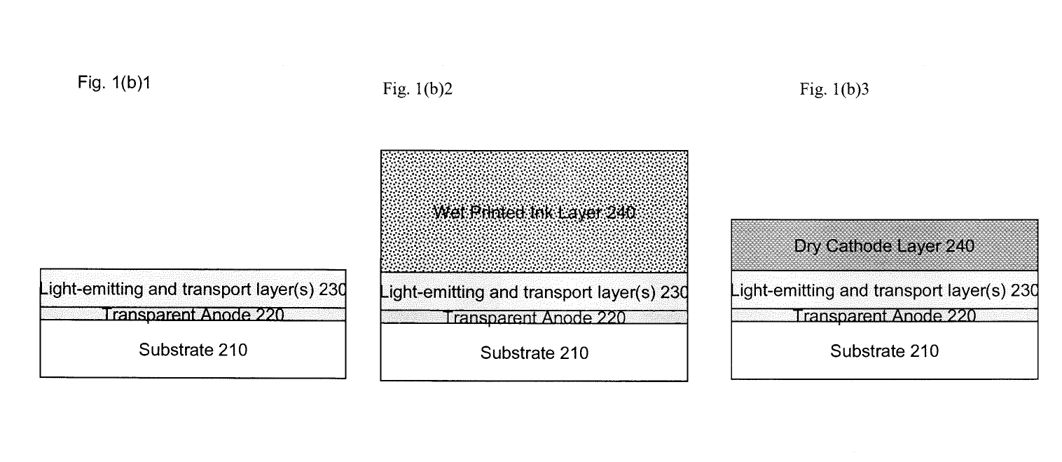

FIGS. 1(b)(1)-(3) illustrates a sequence of cross-sectional diagram of printing an LEPD on flexible substrate according to the present invention. Layer thicknesses are not to scale. As shown, a typical substrate 210 thickness may be between 100 and 200 microns and may be, for example, a plastic substrate composed of polyethylene teraphthalate (PET), poly ethylene napthalate (PEN), poly carbonate (PC) or similar. As with the conventional devices, in some cases, to improve shelf life and product lifetime, the substrate includes a barrier film, composed of inorganic and/or organic materials, which restrict the ingress of water, oxygen and other species into the active areas of the device. Disposed on substrate 210 can be a transparent anode 220, such as indium-tin-oxide (ITO) layer, which can have a thickness between 50-300 nm. A light-emitting polymer 230, with a thickness between 200 nm and 1 micron can be disposed on transparent anode 220. Finally, a cathode 240, which is deposited as a wet printed ink layer and typically results in a dry thickness of between 100 nm and 10 microns, depending on fabrication approach, can be disposed on light-emitting polymer 230.

The cathode ink affected zone (at the interface of polymer 230 and cathode 240) should be reduced below 300 nm, and preferably below 100 nm. The teachings herein describe how to do that, in order to minimize any adverse affects of the wet ink that is used to form the cathode 240 on the polymer 230 below.

In certain embodiments, the printed cathode ink layer thickness can be reduced to a wet thickness as shown in Table III below, although it should be understood that the volume or weight percentage of the solvent within the cathode ink will also have an affect. For Table 1, the characteristics of the conductive ink are preferably >70% solid by weight. In this manner, a thin printed cathode ink layer contains less solvent, resulting in less material to interact with the LEP layer on which it is disposed and less solvent and/or other byproducts to remove in the curing and drying steps. Secondly, solvent and/or other byproduct removal is faster from a thin film, as the transit distance for these components to the free surface, from which these components can escape the sample, is shorter in a thin film. Table 1, below, shows various exemplary printed cathode screen configurations (e.g., plain weave). Of particular interest are the 380 mesh count and higher designs that produce small theoretical ink deposits (and therefore thinner ink films). The mesh opening size can also be considered, as a small mesh opening, as compared to the ink particle size, can lead to clogging.

TABLE III
Screen Mesh Parameters.

| | | | Wet Ink |
|---|---|---|---|
| Mesh Count | Thread Diameter | | Deposit |
| (threads/inch) | (microns) | Open Area | (cm³/m²) |
| 230 | 48 | 27% | 22 |
| 380 | 27 | 27% | 12 |
| 460 | 27 | 20% | 8 |
| 508* | 34 | 9.5% | 4.2 |

*calendered mesh shape

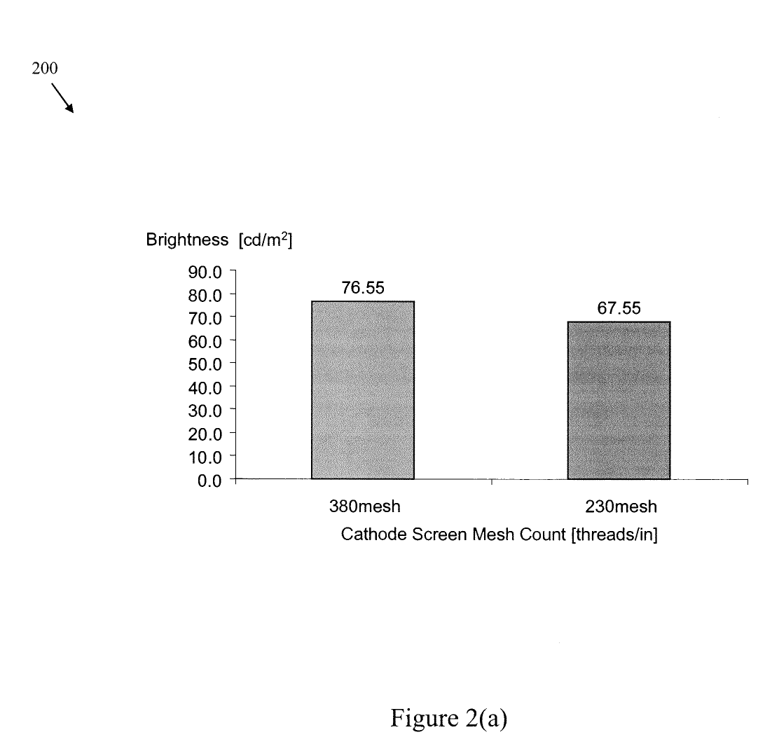

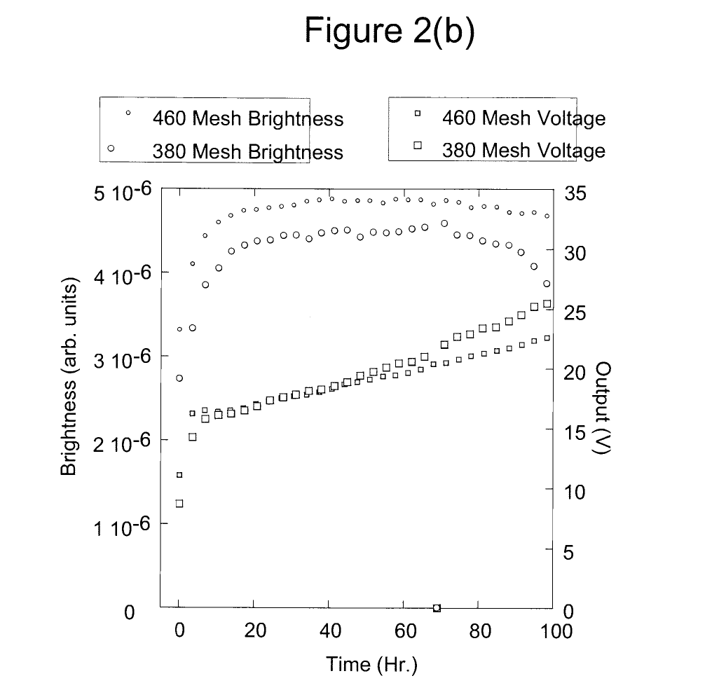

FIG. 2(a) illustrates an example of actual effects 200 of using different cathode ink screen mesh configurations on printed cathode LEPD devices according to certain embodiments. This figure shows averaged experimental data for printed cathode LEPDs where different screen mesh configuration were used to print the same Ag flake-based cathode ink. Varying the cathode screen mesh count varies the ink deposit volume/area and therefore the ink film thickness. In experimental devices, the 380 mesh screen, which has a 45% smaller theoretical ink deposit than the 230 mesh screen (e.g., 12 cm³/m² vs. 22 cm³/m², as presented in Table 1), results in a higher LEPD brightness during continuous, constant current finished display driving (in N2) and at a lower voltage (voltage not pictured here). The 380 mesh screen produces a brightness of about 76.5 cd/A, while the 230 mesh only achieves about 67.5 cd/A. In a further example, a 508 thread/inch calendered mesh screen shows improved voltage and brightness over a device with a thicker cathode printed from a 460 mesh screen, as also shown in Table 1.

FIG. 2(b) shows the impact of different cathode mesh sizes on performance. In the case of the higher 460 mesh count (and reduced ink deposit), the maximum luminance and the persistence of luminance levels under bias stress over time is greater than for the device with a cathode printed from a lower 380 mesh count. Furthermore, the voltage under bias stress over time is also reduced which is an additional benefit of the higher mesh count, reduced ink deposit screen.

It is also noted that the above description discussed printing in the preferred embodiment as screen printing. It is noted that the aspects of this invention relating to cathode layer thicknesses, thermal treatments and drying conditions can also be applied to electrodes printed from inks by gravure, ink jet, coating, offset, spray coating, stencil printing, etc. can also be used within the scope of the invention.

In certain embodiments, the use of a higher mesh count screen for printing of cathode inks can help reduce the thickness of the cathode ink, which may help reduce the amount of ink solvent available to detrimentally interact with the LEP. Having a thinner ink layer can also assist in speeding up solvent removal, since there is less of an overlying ink layer to prevent solvent from escaping from interior regions of the film, particularly those regions closest to the LEP interface. Also, in certain embodiments, the use of calendered mesh screens for cathode deposition can be used to help reduce the deposited ink film thickness. The calendering of screens is a process by which the woven mesh is flattened, resulting in deformation of the threads and reduction of the theoretical ink volume of the mesh by compressing the ink holding volume in the screen. These aspects can be used (or not) alone or in combination with each other, as well as other aspects and embodiments presented herein.

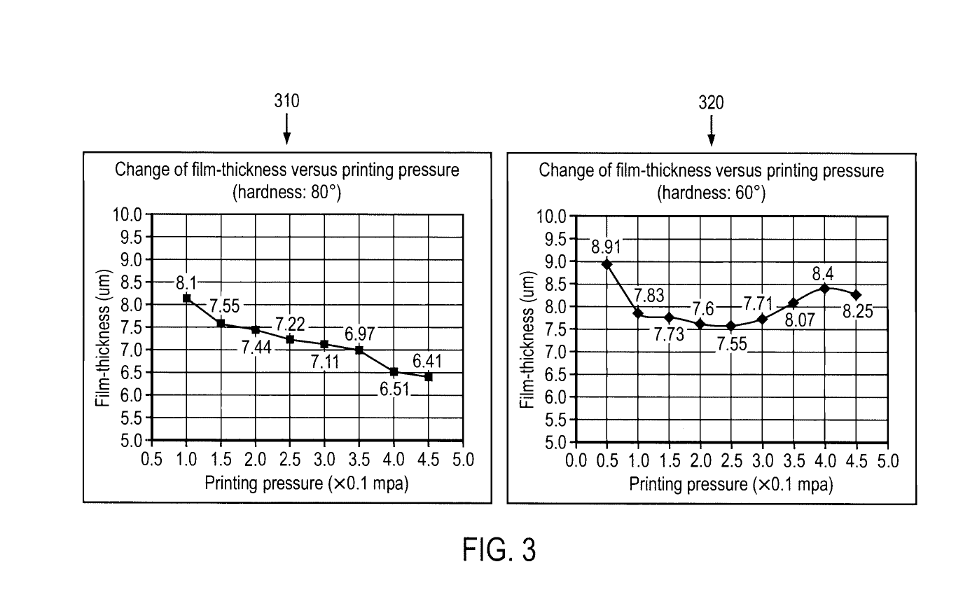

According to certain embodiments, the use of high squeegee pressures and harder squeegees can also be used to minimize printed film thickness. FIG. 3 illustrates an example of the effects of squeegee pressure on film thickness for two different squeegee hardnesses according to certain embodiments (e.g., See, New Long Seimitsu Kogyo Co., Ltd., Tokyo, Japan, http://www.newlong.co.jp/en/technique/user001.html). As shown in FIG. 3, graph 310 shows the effect of printing pressure on screen printed film thickness for a relatively hard squeegee (e.g., 80°) and graph 320 shows the effect of printing pressure on screen printed film thickness for a relatively soft squeegee (e.g., 60°). These graphs illustrate that higher squeegee pressures and for the higher squeegee hardness produces thinner films, which can help improve LEPDs with screen printed cathodes. Thus, in certain embodiments, the use of high squeegee pressures and high hardness squeegees can help decrease cathode ink film thicknesses. Further, in certain embodiments, the cathode ink film thickness can be reduced by using high squeegee angles, low screen gaps (off contact), low down stops, and low emulsion thicknesses.

In certain embodiments, hot plate curing can facilitate rapid heating of LEPDs and/or organic light-emitting devices (OLEDs) on flexile substrates through direct heat transfer from plate to substrate. This can provide very fast cathode ink curing and solvent removal as the sample can be transferred directly from the cathode ink print station to the hot plate in a rapid operation leading to uncured cathode ink residence times of less than 30, or even less than 10, seconds depending on cure temperature. In certain embodiments, during hot plate curing, samples can be heated through the underlying substrate and films, resulting in heating of the bottom of the printed ink film first (i.e., closest to the LEP in a bottom anode/LEP/top cathode printed configuration), which can further result in a higher bottom temperature due to the temperature gradient that normally forms between the heated bottom surface and the cooler, top, free surface. This heating profile through the thickness of the film favors loss of solvent from the bottom surface of cathode ink layer first, which is generally the most critical area of the film as it is in direct contact with the LEP layer. This heating profile can also reduce detrimental skin effects, which can result from curing of the top layer of the printed ink first (i.e., curing the top layer can produce a cured ‘skin’ which can slow solvent and/or curing byproduct removal from the interior of the film).

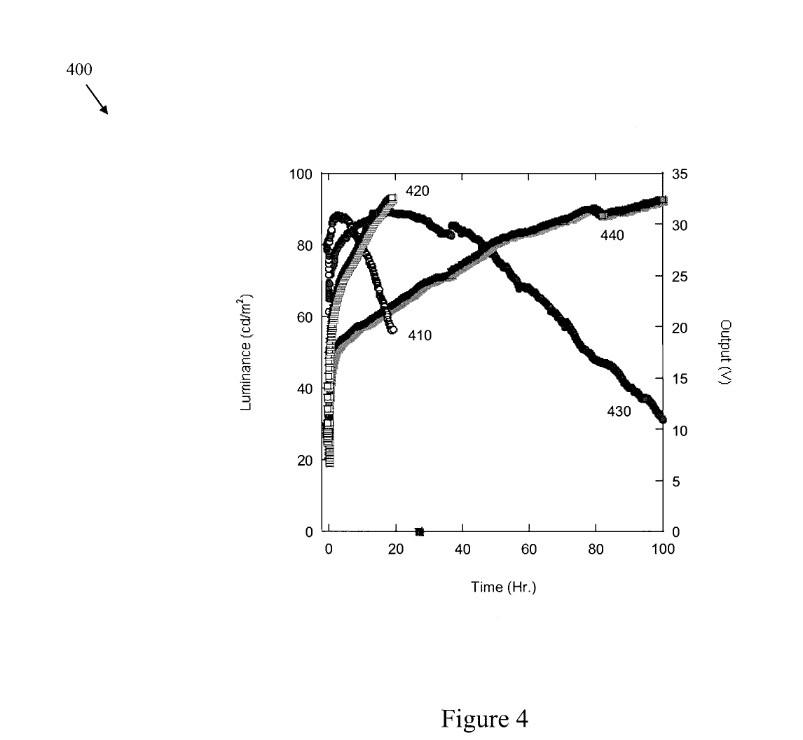

FIG. 4 illustrates resultant brightness comparisons for an LEPD given rapid hot plate cathode ink curing according to certain embodiments versus box oven annealing for an LEPD. Graph 400 includes four sets of data 410-440 that show the brightness (cd/m²) and output voltage (V), both as a function of time, during constant current drive (i.e., 2 mA/cm²) of a one (1) cm² printed cathode LEPD devices with two different post-deposition cathode ink cure processes according to certain embodiments. For the cases shown in FIG. 4, a common substrate, LEP layer, silver paste cathode ink, cathode print parameters and 230 mesh screen were used. Data sets 410, 420 show the luminance and output voltage, respectively, for a 120° C., 10 minute box oven annealing of the cathode print layer. Likewise, data sets 430, 440 show the luminance and output voltage, respectively, for a 145° C., 90 second hot plate cure of the cathode print layer. The rapid curing and solvent removal for the 145° C. hot plate condition (as contrasted to the box oven annealing) approximately tripled the lifetime to half brightness and dramatically extended the time at which the device was able to operate under 30V.

In certain embodiments, rapid printed cathode ink cure can also be facilitated using hot plate curing and a process-specific heating and temperature profile that is induced in the film. For example, a temperature regulated hot plate with a mechanism for good thermal contact and heating uniformity can be used. Further, a nitrogen flow/environment, potentially heated using convection, which typically operates at temperatures of 80-120 degrees Celsius, can be used to help reduce possible oxidation during thermal processing of the cathode ink. A patterned, metal weight frame can be used to press flexible samples against the hot plate to help increase thermal contact, which might increase heating rate and efficiency (i.e., even in a vacuum environment). A vacuum hold down apparatus can also be used to hold down flexible sample and help improve thermal contact. Ambient lighting with no significant spectral components above the LEP absorption edge can be used to help reduce photo-degradation of the LEP layer(s), particularly at high temperatures. A controlled atmosphere (e.g., N2 purge) can be used to help reduce detrimental oxidation at higher temperatures. These aspects can be used (or not) alone or in combination with each other, as well as other aspects and embodiments presented herein.

In certain embodiments, rapid selective heating of a cathode can be used. This step can include either (or both) irradiation from the cathode side or irradiation through infrared (IR) transparent or partially transparent substrates and LEP layers to the IR opaque metal cathode. This form of heating can be easily performed on flexible substrates in sheet or roll-form using a separate heating unit or using an in-line processor in a web. Irradiating through the substrate/LEP side also heats the bottom surface of the cathode ink layer first. This bottom-first heating can lead to solvent removal and curing of the LEP/cathode interface first, which can otherwise be detrimentally effected from prolonged contact to some cathode ink solvent components. Bottom-first heating can also be a more efficient mode of solvent removal as opposed to heating of the top surface, which can lead to skin formation and trapping of detrimental solvents and cure byproducts within the film. Furthermore, the composition of the device layers and/or the spectrum of the IR lamp can be adjusted to reduce thermal absorption and heating in the non-cathode layers (e.g., such as the substrate, LEP, anode, etc.) to reduce degradation of these other layers during the cathode curing process.

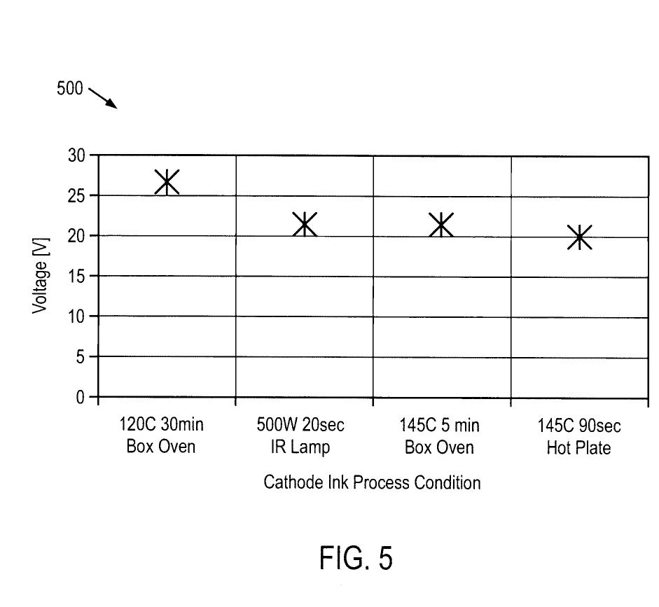

FIG. 5 illustrates IR lamp versus box oven versus hot plate curing data 500 from screen-printed LEPD devices based on Covion SY LEP emitters and a commercially-available silver screen paste ink cathode according to certain embodiments. These data show the decreasing voltage (after 5 hours driving at 2 mA/cm²) of the rapid thermal IR lamp curing versus much slower box oven curing. A number of techniques can be used with this rapid thermal IR treatment on the cathode. For example, an IR lamp can be used in conjunction with an apparatus that holds the substrate at a specific distance away from the lamp to rapidly and uniformly heat and cure the cathode ink. Rotation mechanism, multiple IR light sources, diffusers, and/or similar processing devices can be used to help heating uniformity. IR can also be used for rapid cathode heating in a vacuum environment, as it might not suffer from reduced thermal transfer rates at reduced pressure as a standard oven likely would. IR can additionally be used in combination with an inert gas (e.g., nitrogen, etc.) environment to help reduce oxidation reactions during thermal processing. These aspects can be used (or not) alone or in combination with each other, as well as other aspects and embodiments presented herein.

In certain embodiments, fast heating can be achieved by directing a heated gas stream at the LEPD, for example, the substrate. This can quickly deliver heat to the LEP/cathode ink interface, as well as accelerate drying by removing ink solvent and byproducts from the ink film surface and near surface area, while maintaining a high concentration gradient between the film, film surface and the adjacent ambient atmosphere. A further embodiment includes the use of an inert gas to limit oxidation. In a further embodiment, the heated inert gas process is preceded by an inert gas wash, or purge, that clears the ink area of oxygen and water prior to the application of heat to prevent unwanted oxidation of the cathode material and/or the underlying LEP-containing layers. This could be achieved in a gas stream apparatus in which the heating element could be activated after some purge period.

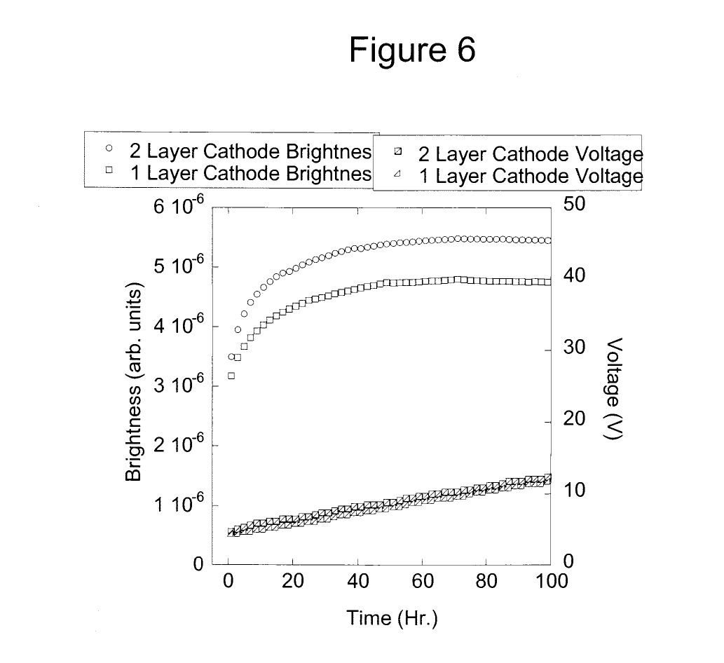

FIG. 6 illustrates a comparison of screen-printed LEPD device performance (luminance vs. time under constant current drive) for devices with a single cathode layer and devices with a multilayered printed cathode. In the case of the multilayer device, the maximum luminance levels under bias stress over time is greater than the single layer cathode device.

In certain embodiments, it can be advantageous to deposit the cathode or interconnects as multiple cathode and/or interconnect layers, as opposed to depositing in a single layer. This can serve to increase conductivity, ensure that all metal particles are electrically connected to the cathode, improve nestling and particle contact and other effects. For a cathode or interconnect, it is more advantageous to deposit this as series of thinner layers as opposed to a single thick layer or a multitude of thick layers as the thin layer approach can promote more rapid drying and expose the LEP to less detrimental solvents or other materials that adversely affect the LEP, particularly when the film is wet or incompletely dried. These thin layers can be achieved by the screen variations discussed above based on low ink deposit configurations.

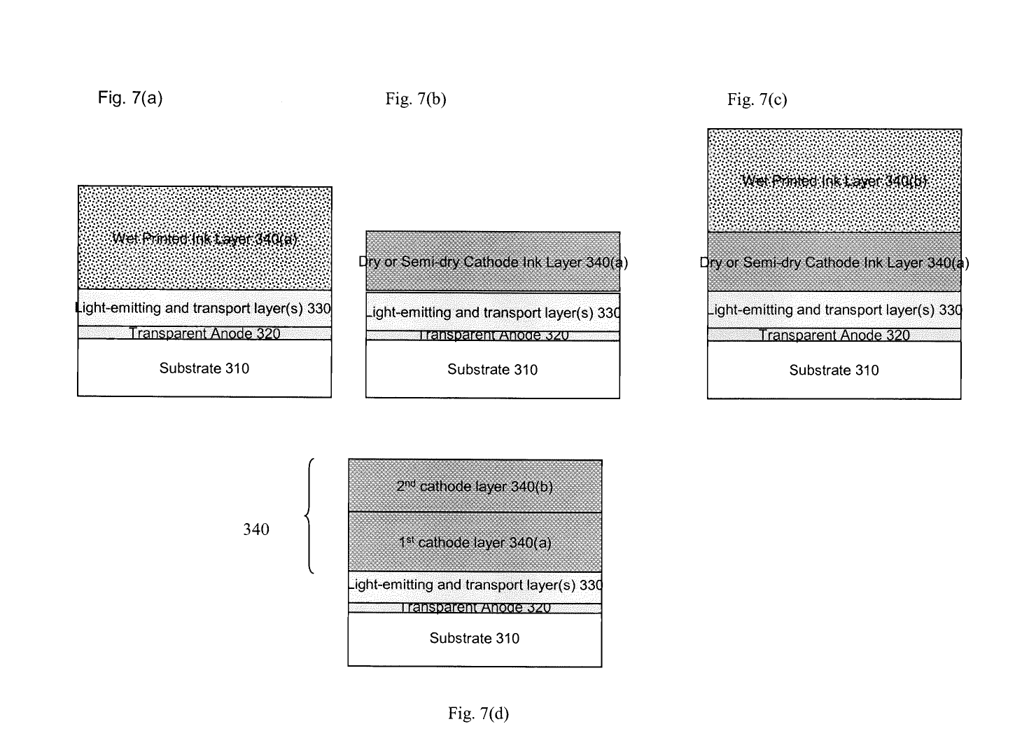

FIGS. 7(a)-(d) illustrate printing of a cathode using multiple thin cathode layers according to the present invention as described above using a sequence of cross-sectional diagrams of printing an LEPD on flexible substrate. Layer thicknesses are not to scale. As shown, a typical substrate 310 thickness may be between 50 and 200 microns and may be, for example, a plastic substrate composed of polyethylene teraphthalate (PET), poly ethylene napthalate (PEN), poly carbonate (PC) or similar. As with the conventional devices and the embodiment described above, in some cases, to improve shelf life and product lifetime, the substrate includes a barrier film, composed of inorganic and/or organic materials, which restrict the ingress of water, oxygen and other species into the active areas of the device. Disposed on substrate 310 can be a transparent anode 320, such as indium-tin-oxide (ITO) layer, which can have a thickness between 50-300 nm. A light-emitting polymer 330, with a thickness between 200 nm and 1 micron can be disposed on transparent anode 320. Finally, a cathode 340, which is deposited as a multiple wet printed ink layers 340(a) and 34(b) as shown in FIGS. 7(a) and 7(c)) and results in a cathode 340 composed of the dried layers 340(a) and 34(b), in which a dry thickness of the entire cathode 340 is between 100 nm and 10 microns.

Multilayer printing allows for the benefits of thick films: reduced resistance, less conducting particle isolation, and better thermal conductivity away from active layer while minimizing wet cathode ink interactions with active layer. Multi-step printing reduces solvent interaction by minimizing wet ink on active layer surface. Also, the 1st printed layer can provide a barrier to 2nd layer interaction with substrate. This technique also enables use of functional multilayer printing of high stability and or high injection efficiency cathode interface materials, such as carbon, gold, etc. but with enhanced conductivity and/or reduced cost by use of a high conductivity silver layer for the top ‘interconnect layer’ which provide low resistance electrical connectivity.

Although the present invention has been particularly described with reference to embodiments thereof, it should be readily apparent to those of ordinary skill in the art that various changes, modifications, substitutes and deletions are intended within the form and details thereof, without departing from the spirit and scope of the invention. For example, in the claims set forth below, various different combinations of dependent claims not specifically recited are intended as being within the scope of the invention. Accordingly, it will be appreciated that in numerous instances some features of the invention will be employed without a corresponding use of other features. Further, those skilled in the art will understand that variations can be made in the number and arrangement of inventive elements illustrated and described in the above figures. It is intended that the scope of the appended claims include such changes and modifications.

1. A method of forming an organic light emitting device comprising the steps of:
forming a conducting layer electrode over a substrate;
forming an organic light emitting layer over the conducting layer electrode;
forming another conducting electrode over the organic light emitting layer, the step of forming including the steps of:
printing a conductive ink containing a solvent therein over the organic light emitting layer, wherein the step of printing applies the conductive ink in an amount that is <about 22 cm³ of ink/m² to the organic light emitting layer; and
curing the conductive ink to obtain the another conducting electrode of the organic light emitting device, wherein detrimental interactions between the conductive ink and the organic light emitting layer are substantially prevented by one or more of the following steps
(1) the step of curing includes rapidly curing the conductive ink so that within about 1 minute from the initiation of the step of curing, a majority of the solvent evaporates, and
(2) the step of printing includes selecting the solvent so that the solvent is less than 40% by weight of the conductive ink

2. The method according to claim 1 wherein the step of printing further includes printing the conductive ink such that the conductive ink includes less than 10 g solvent/m2 of printed area.

3. The method according to claim 2 wherein the rapidly curing the conductive ink so that within about 1 minute from the initiation of the step of curing the majority of the solvent evaporates is used as the one or more following steps.

4. The method according to claim 3 wherein the selecting the solvent so that the solvent is less than 40% by weight of the conductive ink is further used as the one or more following steps.

5. The method according to claim 1 wherein the rapidly curing the conductive ink so that within about 1 minute from the initiation of the step of curing the majority of the solvent evaporates is used as the one or more following steps.

6. The method according to claim 5 wherein the selecting the solvent so that the solvent is less than 40% by weight of the conductive ink is further used as the one or more following steps.

7. The method according to claim 6, wherein a thickness of the conductive ink is less than 10 microns.

8. The method according to claim 1 wherein the selecting the solvent so that the solvent is less than 40% by weight of the conductive ink is used as the one or more following steps.

9. The method according to claim 1 wherein the step of forming the organic light emitting layer includes the steps of forming a polymer layer, and the polymer layer has a distributed average concentration of hole transport materials, electrolytes, surfactants, dopants, salts, and interface dipole enhancing materials.

10. The method according to claim 1 wherein the step of forming the organic light emitting layer includes a polymer layer, and the steps of forming a stratified concentration of hole transport materials, electrolytes, surfactants, dopants, salts, and interface dipole enhancing materials.

11. The method according to claim 1, wherein a thickness of the conductive ink is less than 10 microns.

12. The method according to claim 1, wherein a thickness of the conductive ink is less than 5 microns.

13. The method according to claim 1, wherein a thickness of the conductive ink is less than 3 microns.

14. The method according to claim 1, wherein the step of printing is screen printing that uses a conductor screen mesh of ≧230 threads per inch.

15. The method according to claim 1, wherein the step of printing is screen printing that uses a conductor screen mesh of ≧380 threads per inch.

16. The method according to claim 1, wherein the step of printing is screen printing that uses a conductor screen mesh of ≧460 threads per inch.

17. The method according to claim 1, wherein the step of printing is screen printing that uses a conductor screen mesh of ≧508 threads per inch.

18. The method according to claim 1, wherein the step of printing applies the conductive ink in an amount that is <about 12 cm³ of ink/m² to the organic light emitting layer below.

19. The method according to claim 1, wherein the step of printing applies the conductive ink in an amount that is <about 8 cm³ of ink/m² to the organic light emitting layer below.

20. The method according to claim 1, wherein the step of printing applies the conductive ink in an amount that is <about 4.2 cm³ of ink/m² to the organic light emitting layer below.

21. The method according to claim 1 wherein the step of printing includes the step of applying the conductive ink using a calendered top conductor screen printing mesh.

22. The method according to claim 1 wherein the step of printing includes the step of forcing a portion of applied conductive ink through one of a screen and stencil using a screen printing squeegee of >60 durometer.

23. The method according to claim 1 wherein the step of printing includes the step of forcing a portion of applied conductive ink through one of a screen and stencil using a screen printing squeegee of >70 durometer.

24. The method according to claim 1 wherein the step of printing includes the step of forcing a portion of applied conductive ink through one of a screen and stencil using a screen printing squeegee of >80 durometer.

25. The method according to claim 1 wherein the step of printing includes the step of forcing a portion of applied conductive ink through one of a screen and stencil using a screen printing squeegee of >60 durometer.

26. The method according to claim 1 wherein the step of printing includes the step of forcing a portion of applied conductive ink through one of a screen and stencil using a screen printing squeegee of >70 durometer.

27. The method according to claim 1 wherein the step of printing includes the step of forcing a portion of applied conductive ink through one of a screen and stencil using a screen printing squeegee of >80 durometer.

28. The method according to claim 1, wherein the step of rapidly curing is used as the one step, and at least one process of heating at greater than room temperature and flowing air over the conductive ink is used to obtain using the rapid curing.

29. The method according to claim 28, wherein the at least one process is initiated within one of 10, 5, and 2.5 seconds after the step of applying.

30. The method according to claim 28, wherein the at least one process includes introducing heat from underneath the substrate such that there is a temperature gradient from higher temperature at an interface between the applied conductive ink and the light emitting polymer layer to a lower temperature at a top of the conductive ink.

31. The method according to claim 28, wherein the at least one process uses a hot plate for heating.

32. The method according to claim 28, wherein the at least one process uses a vacuum to hold the substrate in contact with a heat source to aid in rapid heating of the conductive ink.

33. The method according to claim 28, wherein the at least one process uses a mechanical frame to hold the substrate in contact by one of mechanical force and weight with a heat source to aid in rapid heating of the conductive ink.

34. The method according to claim 1, wherein the step of curing is performed at least some of the time in a vacuum.

35. The method according to claim 1, wherein the step of curing is performed at least some of the time in an inert gas.

36. The method according to claim 1, wherein the step of curing includes a plurality of steps, with a first curing step including purging using an inert gas.

37. The method according to claim 1, wherein the step of curing uses a high temperature curing environment, and a vacuum load lock is used for the high temperature curing.

38. The method according to claim 1 further including the step of eliminating light from being absorbed into the light emitting polymer layer during the step of curing.

39. The method according to claim 1, wherein, during the step of curing, exposures to temperatures >120 C atmospheres containing >1 ppm of oxygen or water are limited to less than 600 seconds.

40. The method according to claim 1, wherein, during the step of curing, exposures to temperatures >120 C atmospheres containing any of >1 ppm of oxygen or water are limited to less than 90 seconds.

41. The method according to claim 1, wherein, during the step of curing, exposures to temperatures >140 C atmospheres containing >1 ppm oxygen or water are limited to less than 90 seconds.

42. The method according to claim 1, wherein, during the step of curing, exposures to temperatures >140 C atmospheres containing >1 ppm oxygen and water or limited to less than 20 seconds.

43. The method according to claim 1 wherein the step of curing includes the step of displacing one of oxygen, ozone, water, and byproducts of the conductive ink using an inert gas.

44. The method according to claim 1, wherein the step of curing includes the step of flowing a heated gas over a top surface of the conductive ink.

45. The method according to claim 44, wherein the heated gas has a temperature of <140 C.

46. The method according to claim 44, wherein the heated gas has a temperature of <120 C.

47. The method according to claim 44, wherein the heated gas has a temperature of <90 C.

48. The method according to claim 47 wherein the step of flowing uses an inert gas.

49. The method according to claim 1 wherein the step of curing uses radiation to thermally treat the conductive ink.

50. The method according to claim 49, wherein the radiation used has a spectrum that is selectively absorbed by the conductive ink.

51. The method according to claim 49, wherein the radiation used is infrared radiation.

52. The method according to claim 49, wherein the radiation is directed to pass through the substrate and the organic light emitting layer to reach the conductive ink.

53. The method according to claim 49, wherein the step of curing is conducted in a vacuum.

54. The method according to claim 49, wherein the step of curing is conducted in an inert gas.

55. The method according to claim 49, wherein the step of curing includes the step of removing heat from the substrate using a solid appliance heat sink to maintain a higher temperature at the conductive ink than at the light emitting polymer layer.

56. The method according to claim 1 wherein the steps of forming the another conductive layer and curing are each sequentially repeated a plurality of times in order to obtain the another conducting electrode that is formed from a plurality of the another conductive layers.

57. The method according to claim 56 wherein the steps of curing thermally dries the another conductive layer prior to the repeating the step of forming another conductive layer.

58. The method according to claim 56 wherein each of the another conductive layer applied in each of the plurality of steps of forming the another conductive layer has a different composition.

59. The method according to claim 56 wherein at least a first one of the conductive layers that is directly formed over the organic light emitting layer is formulated to enhance injection characteristics and a last one of the conductive layers that is formed over a previous one of the conductive layers is formulated to enhance its conductivity characteristics.

60. The method according to claim 56 wherein another conductive layer that is directly over the organic light emitting layer has a smaller particles than particles that are in the another conductive layer that is applied when the step of forming the another conductive layer is repeated.

61. The method according to claim 1 wherein the step of printing uses one of stencil printing, gravure printing, ink jet printing, coating, offset printing, and spray coating.
